(19) United States
(12) Patent Application Publication
(10) Pub. No.: US 2021/0187663 A1
(43) Pub. Date: Jun. 24, 2021

(54) METHOD OF CUTTING SEMICONDUCTOR SUBSTRATES AND CORRESPONDING SEMICONDUCTOR PRODUCT

(71) Applicant: STMicroelectronics S.r.l., Agrate Brianza (MB) (IT)

(72) Inventors: Antonio BELLIZZI, Milano (IT); Michele DERAI, Milano (IT)

(73) Assignee: STMicroelectronics S.r.l., Agrate Brianza (MB) (IT)

(21) Appl. No.: 17/121,184

(22) Filed: Dec. 14, 2020

(30) Foreign Application Priority Data
Dec. 18, 2019 (IT) 102019000024436

(51) Int. Cl. B23K 26/38; H01L 21/304

(52) U.S. Cl. CPC B23K 26/38; B23K 2101/40; H01L 21/3043

(57) ABSTRACT

A semiconductor substrate such as a semiconductor wafer includes a cutting line having a length. The semiconductor substrate is cut along the line by first selectively applying laser beam ablation energy to the semiconductor substrate a certain locations along the cutting line and then blade sawing along cutting line. The semiconductor substrate thus includes one or more ablated regions as well as one or more unablated regions at the cutting line.

### PRIORITY CLAIM

This application claims the priority benefit of Italian Application for Patent No. 102019000024436, filed on Dec. 18, 2019, the content of which is hereby incorporated by reference in its entirety to the maximum extent allowable by law.

### TECHNICAL FIELD

The description relates to cutting semiconductor substrates (wafers).

One or more embodiments may be applied, for instance, in removing from semiconductor substrates the integrated circuitry associated with test element groups (TEGs).

### BACKGROUND

Semiconductor substrates (“wafers”) are conventionally cut, during so-called “singulation” of individual semiconductor chips or dice, for instance.

Cutting may involve wafer sawing, namely cutting by blades.

Sawing may be advantageous due to its capability of following cutting (scribe) lines which may contain integrated circuitry for test element group (TEG) patterns. These integrated circuitry may exhibit material non-uniformity (metal versus dielectric notably), which may make TEGs critical to be removed by blade cutting. In fact, non-uniformity may possibly lead to chipping/cracks induced in the silicon and dangling material on metals.

In some technologies, cutting may involve an (additional) laser grooving step, where a first channel is created over (the whole length of) a desired cutting line by applying laser beam energy with cutting completed using blades.

Laser grooving too may induce damage in silicon metal layers/dielectrics. Also, while certain laser-based technologies (“Hasen cut”, for instance, where a laser is repetitively turned on-off during laser processing) may facilitate processing different shapes depending on an on-off setting, conventional laser grooving does not admit easy modifications of laser parameters along a sawing path.

Other technologies such as plasma dicing can be resorted to with the possibility of avoiding undesired chipping counterbalanced by the process being limited to wafers without metals in the scribe lines.

Additionally, despite certain possible advantages, conventional cutting techniques may exhibit drawbacks such as long process time, die strength reduction, active area contamination if not properly protected.

There is a need in the art to contribute in overcoming the drawbacks discussed in the foregoing.

### SUMMARY

One or more embodiments may relate to a method.

One or more embodiments may relate to a corresponding semiconductor product.

One or more embodiments may be applied to cutting virtually any type of semiconductor substrate or product including such a substrate.

One or more embodiments may provide a wafer dicing process which can be made somewhat “aware” of a test structure design along a sawing path. One or more embodiments may thus facilitate relaxing front-end/back-end (FE/BE) constraints.

In one or more embodiments, prior to conventional blade sawing, laser ablation can be applied (only) to certain critical portions (TEGs to be removed, for instance). Process time can thus be reduced in comparison with conventional laser grooving step and damage caused by thermal effects on die sidewalls and top metals can be likewise reduced.

In one or more embodiments, desired laser ablation target areas can be identified based on a graphic database system (GDS) information for a certain chip.

One or more embodiments may provide semiconductor products having one or more cut edges including ablated portions (fused) which can be distinguished from portions resulting (only) from saw cutting, insofar as these latter portions may exhibit striation, for instance.

### BRIEF DESCRIPTION OF THE DRAWINGS

One or more embodiments will now be described, by way of example only, with reference to the annexed figures, wherein:

FIG. 1 is exemplary of a possible context of use of embodiments;

FIG. 2 is exemplary of the possible result of conventional blade sawing at a cutting line in a semiconductor substrate;

FIG. 3 is a view essentially along arrow III in FIG. 1, the view being reproduced on an enlarged scale and being exemplary of the possible result of selective laser ablation at a cutting line in embodiments;

FIG. 4 is exemplary of the possible result of blade sawing after selective laser ablation as exemplified in FIG. 3; and

FIG. 5 is exemplary of possible laser ablation patterns in embodiments.

It will be appreciated that, for the sake of clarity and ease of description, the various figures may not be drawn to a same scale.

### DETAILED DESCRIPTION

In the following description, various specific details are given to provide a thorough understanding of various exemplary embodiments of the present specification. The embodiments may be practiced without one or several specific details, or with other methods, components, materials, etc. In other instances, well-known structures, materials, or operations are not shown or described in detail in order to avoid obscuring various aspects of the embodiments. Reference throughout this specification to “one embodiment” or “an embodiment” means that a particular feature, structure, or characteristic described in connection with the embodiment is included in at least one embodiment. Thus, the possible appearances of the phrases “in one embodiment” or “in an embodiment” in various places throughout this specification are not necessarily all referring to the same embodiment. Furthermore, particular features, structures, or characteristics may be combined in any suitable manner in one or more embodiments.

The headings/references provided herein are for convenience only, and therefore do not interpret the extent of protection or scope of the embodiments.

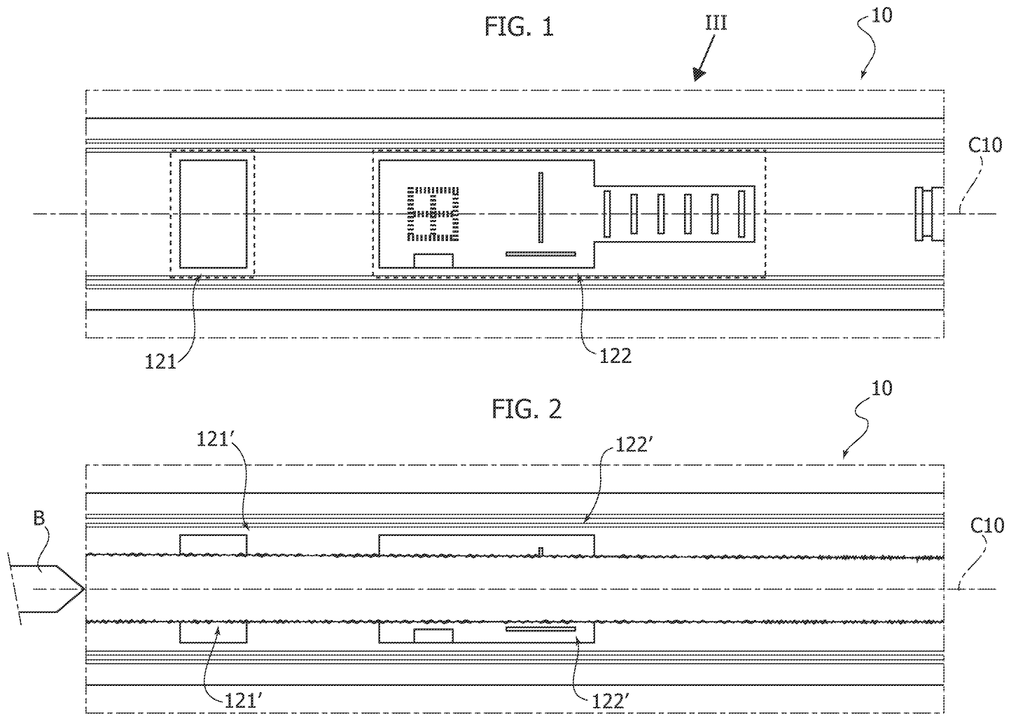

Reference is made to FIGS. 1 and 2. As already discussed in the foregoing, sawing by means of blades is a conventional approach adopted in cutting a semiconductor substrate 10 (a semiconductor wafer of any known type will be referred throughout in the following for simplicity) at a cutting line C10.

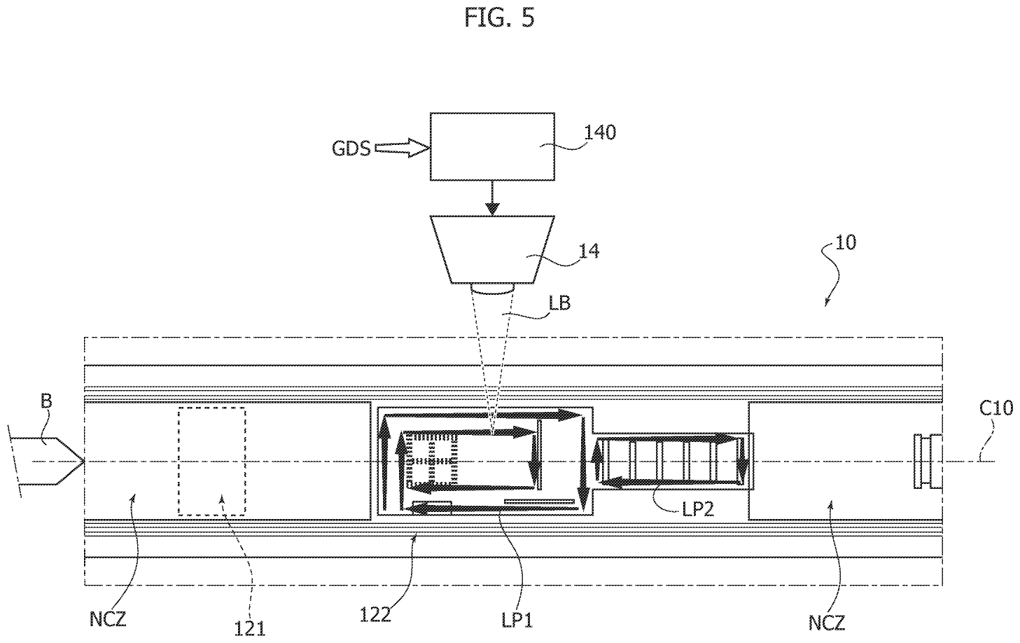

Again for simplicity the line C10 will be assumed to be a straight line: as discussed in the following (in connection with FIG. 5, for instance), one or more embodiments may however exhibit flexibility in the cutting direction.

As exemplified in FIG. 1, cutting the wafer 10 at the line C10 may involve cutting through (and practically removing) the integrated circuitry associated with one or more test element group (TEG) patterns. The integrated circuitry for two of these TEGs, designated 121 and 122, are illustrated by way of example in FIG. 1.

Certain TEGs, such as TEGs with a simple shape and/or a short length in the direction of the cutting line, are not particularly critical for blade cutting: the short rectangular TEG 121 on the left-hand side of FIG. 1 is exemplary of these.

Conversely, other TEGs such as the TEG 122 at the center of FIG. 1, having an inhomogeneous shape and/or a certain length in the direction of the cutting line, may turn out to be critical for blade cutting.

It is noted that shape and/or length of a TEG can be primarily related to the top metal of the integrated circuitry as visible in certain ones of the figures herein.

These critical TEGs are likely to exhibit chipping as a result of blade sawing which may damage the associated device (an integrated circuit or IC, for instance) and/or affect its reliability.

This undesired effect is schematically represented in FIG. 2, where two pairs of remainders 121′ and 122′ of TEGs 121 and 122 are shown on both sides of the cutting line C10 resulting from blade sawing of the wafer 10 as schematically indicated at B on the left-hand side of FIG. 2.

This may result in a severe situation with chipping affecting the touch groove of the device: this situation is critical insofar as it can lead to device failure during operation.

Even without wishing to be bound to any specific theory in that respect, a possible explanation of the criticality of removing certain TEGs using blades may lie in the non-uniformity in the material to be sawn, which may induce chipping/cracks in the silicon and “dangling” material on metals.

Two main properties can be regarded as likely to make a TEG critical: TEG length (in the direction of the cutting line C10) and TEG shape.

Longer TEGs with complex shapes (see 122 in FIG. 1, for instance) are the most critical ones and the most likely to cause chipping as a result of sawing the wafer.

Laser grooving as conventionally practiced may likewise induce damage in silicon metal layers/dielectrics. Also, changing laser parameters along the cutting path may be critical in conventional laser grooving using a laser machine able to ablate only selected geometries.

For that reason, laser grooving can be used for certain types of wafer (Low-K materials, that is materials having a small relative dielectric constant relative to silicon dioxide are exemplary of these) in order to facilitate subsequent blade sawing by creating a groove along—the whole of—the wafer cutting path street.

This may provide improved sawing quality but leads to a longer process time and to a reduction in die strength.

It is observed that laser grooving can also induce damages at the die sides and may require protecting active areas during laser processing in order to counter undesired active area contamination if not properly protected.

It is similarly observed that, while countering chipping, plasma dicing is hardly compatible with metal TEGs in the sawing path. Also, plasma dicing is a high-cost technology.

One or more embodiments may be based on the recognition that selective removal (at least partial) of critical TEGs by laser beam energy (ablation) may facilitate a smoother subsequent blade sawing action while dispensing with the drawbacks of conventional cutting technologies as discussed in the foregoing.

Such removal being “selective” indicates that, in one or more embodiments, laser beam ablation energy can be applied only to certain locations (the “critical” TEG 122 of FIG. 1, for instance) while refraining from applying laser beam ablation energy to other locations (the “non-critical” TEG 121 of FIG. 1, for instance).

As discussed in connection with FIG. 5 below, selective application of laser beam energy (for TEG removal, for instance) can follow a desired pattern, for instance a curvilinear (non straight) path as a function of TEG design and location along the cutting line C10.

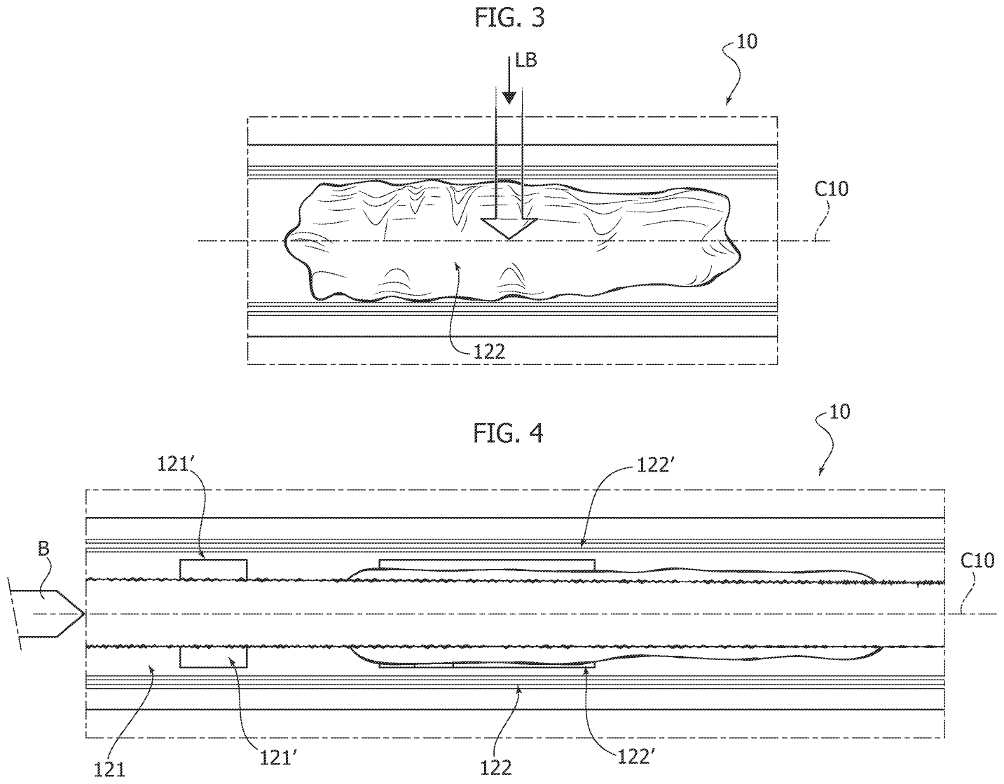

FIG. 3 exemplifies a possible result of ablation via laser beam LB applied (only) at a TEG such as 122 and FIG. 4 exemplifies sawing (blade cutting as again schematically indicated at B on the left-hand side of FIG. 4) performed along the cutting line C10 in such a way as to cover both the previously ablated region (at the critical TEG 122) and the non-ablated region (at the non-critical TEG 121).

One or more embodiments may thus facilitate selective reliable removal of critical TEGs via laser beam energy.

Process time is thus reduced in comparison with conventional laser grooving (performed over the whole length of the cutting line) while laser-induced thermal effects on die sidewalls and top metals are also reduced.

Undesired effects of conventional blade cutting such as chipping can be similarly reduced, thus providing semiconductor substrates (wafers) having cut edges substantially exempt from chipping.

As used herein, “substantially exempt from chipping” is intended to identify a cut edge in a semiconductor substrate that the skilled person in the field of manufacturing devices comprising semiconductor substrates (semiconductor wafers) would consider exempt from chipping/cracks.

In one or more embodiments, a TEG can be identified as expectedly critical for wafer sawing based on manufacturing specifications such as graphic database system (GDS) information, for instance, as related to TEG material/TEG geometry (especially long shaped TEGs).

In one or more embodiments only some TEGs can thus be “burned away” (ablated) by laser beam. This results in faster processing in comparison to laser grooving applied to the whole of the cutting (scribe) line.

One or more embodiments facilitates improved process tuning insofar as laser beam parameters can be selected (tailored) for each individual TEG on the basis of graphic database system (GDS) information, for instance, with the capability of following TEG geometry.

As exemplified in FIG. 5, in one or more embodiments, a laser beam LB from a laser source 14 (of a known type, see below) can be “steered” under the control of conventional laser beam control circuitry 140 as known to those of skill in the art over the geometry of a whole region (a critical TEG, for instance) along possibly non-linear scanning paths as exemplified by spiral and closed loop trajectories LP1, LP2 in FIG. 5 with the ability of choosing adequate laser pattern parameters/strategies tailored for each different region (TEG, for instance).

As exemplified in FIG. 5, the laser beam LB can thus be caused to “jump” only to locations to be ablated (critical TEGs such as 122 for instance) without affecting neighboring “no-cut” (no laser cut) zones NCZ possibly including one or more non-critical TEGs such as 121.

In that respect, one or more embodiments may rely (in comparison with conventional Hasen cut technology, for instance) on one or more of the following features: the location of the edges of the laser on/off areas can be made dependent on the beginning/end of a TEG along the cutting line (based on GDS information as made available to the laser control circuit 140, for instance); the lateral extension or width of the ablation area, transverse to the cutting line C10, can be likewise varied depending on the TEG shape (based on GDS information as made available to the laser control circuit 140, for instance), as shown, for example, with the different widths of the trajectories LP1, LP2); and ablation per se (ablation energy) can also be selective with respect to the shape and/or length of the TEG.

One or more embodiments are adapted to be implemented by various types of lasers currently available with various suppliers such as LPKF Laser & Electronics (see lpkf.com), Coherent®/Rofin (see rofin.com) or Arges GmbH (see arges.de). Laser sources suited for use in embodiments may include, by way of non-limiting example UV, (sub)picosecond as well as infrared, green and femtosecond lasers.

One or more embodiments facilitate achieving a high flexibility in selecting operating parameters as a function of various types of semiconductors regions to be ablated (TEGs being just exemplary of these).

Possible ranges of operating parameters in embodiments may comprise: for pulsed lasers, pulse repetition rates from 50 kHz to 2000 kHz for pico with values of 100 MHz for femto; laser beam power from 0.5 to 2 W (low power), with higher power values such as, say 50 W, not expected to be involved in most applications; laser beam spot diameter at substrate from 10 micron to 100 micron (assuming circular shape); specific laser beam power applied to substrate tunable depending on substrate type, as would be the case, for instance, of dielectric versus metal this may be from 25 to 1600 W/mm²; scanning speed of laser beam from 500 to 10000 mm/s; laser beam energy per unit length of cutting line from 0.000125 J/mm² to 0.008 J/mm²; ablation depth in a range of 20 to 40 micron (adequate to remove TEGs); ablation width in a range of 20 to 60 micron (covers TEG width while less than scribe line full width); and percentage of cutting line length to which ablation is applied in a range of 5 to 40% depending, for instance, on number of critical TEGs identified.

For instance, in the case of laser ablation limited to a small amount critical TEG, exemplary laser parameters may include: power=1.5 W; pulse frequency=400 kHz; scanning speed=500 mm/s; spot diameter=23 micron; spot overlap=15 micron; and job repetitions=10.

In one or more embodiments, the heating-affected zone of semiconductor is reduced and laser process time may be less than halved in comparison with conventional laser grooving.

One or more embodiments may facilitate reducing burned/melted particles after laser scanning insofar as less material is melted, in comparison with laser grooving.

Processing costs can be reduced in comparison with processes involving protection to counter active area contamination.

As discussed, laser beam ablation energy can be easily tuned (to selectively remove TEGs, for instance) possibly adopting real-time laser parameter adjustment (as implemented at 140, for instance) fitting each single TEG in the cutting (scribe) line.

One or more embodiments provide appreciable improvement in sawing quality, by dispensing with chipping induced by blade sawing which may extend up to the active area of a semiconductor chip (in the region of critical TEGs, for instance).

As exemplified herein, a method of cutting a semiconductor substrate (for instance, 10) at a cutting line (for instance, C10) having a length may comprise: selectively applying laser beam ablation energy (for instance, LB, 14) to the semiconductor substrate at said cutting line, wherein the semiconductor substrate comprises at least one ablated region (for instance, at 122) and at least one unablated region (for instance, at 121 or NCZ) at said cutting line, and blade sawing (for instance, B) said semiconductor substrate over the (whole) length of said cutting line, wherein said semiconductor substrate is cut both at said at least one ablated region and at said at least one unablated region as a result of said blade sawing (B).

In a method as exemplified herein, the semiconductor substrate may comprise at least one chipping-prone region (for instance, at TEG 122) at said cutting line and the method may comprise applying laser beam ablation energy to said at least one chipping-prone region wherein said semiconductor substrate is cut at said at least one laser beam ablated chipping-prone region as a result of said blade sawing in the substantial absence of chipping at said least one chipping-prone region.

In a method as exemplified herein: the semiconductor substrate may comprise at least one test element group, TEG (for instance, 122) at said cutting line; and the method may comprise applying laser beam ablation energy to said at least one test element group, TEG at said cutting line, wherein said semiconductor substrate is cut at said test element group, TEG at said cutting line as a result of said blade sawing.

In a method as exemplified herein: the semiconductor substrate may comprise a plurality of test element groups, TEGs (for instance, 121, 122) at said cutting line; and the method may comprise leaving at least one test element group, TEG (for instance, 121) in said plurality of test element groups, TEGs (for instance, 121, 122) exempt from application of laser beam ablation energy, wherein said semiconductor substrate is cut at said at least one test element group, TEG left exempt from application of laser beam ablation energy (only) as a result of said blade sawing.

A method as exemplified herein may comprise selecting (based on GDS information/data, for instance) out of said plurality of test element groups, TEGs (for instance, 121, 122) said at least one test element group, TEG (for instance, 121) left exempt from application of laser beam ablation energy (as a function of one of the shape or the length thereof along said cutting line.

A method as exemplified herein may comprise selecting out of said plurality of test element groups, TEGs (for instance, 121, 122) said at least one test element group, TEG (for instance, 121) left exempt from application of laser beam ablation energy as a test element group having a length less than a critical length along said cutting line.

A method as exemplified herein may comprise selecting said critical length along said cutting line approximately equal to 250 micron.

In a method as exemplified herein, selectively applying laser beam ablation energy to the semiconductor substrate may comprises scanning a laser beam in a curvilinear path (see, for instance, the spiral-like paths LP1, LP2 in FIG. 5) over at least one region (122) of the semiconductor substrate (10) arranged at said cutting line (C10).

A semiconductor product as exemplified herein may comprise may comprise a semiconductor substrate (for instance, 10) having at least one edge cut at a cutting line (for instance, C10) having a length (either of the edges illustrated in FIG. 4 above and below the cutting line C10 may be exemplary of such a cut edge), wherein said at least one edge comprises at least one laser beam ablated region (for instance, 122′) and at least one unablated region (for instance, 121′), wherein said at least one edge is blade cut (for instance, B) over the length of said cutting line both at said at least one ablated region and at said at least one unablated region.

A semiconductor product as exemplified herein may comprise at least one remainder (for instance, 122′) of cutting a test element group, TEG (for instance, 122) at said at least one edge, wherein said at least one edge comprises a laser beam ablated region at said at least one remainder (for instance, 122′) of cutting a test element group, TEG (122).

A semiconductor product as exemplified herein may comprise plurality of remainders (for instance, 121′, 122′) of cutting test element groups, TEGs at said at least one edge, wherein at least one remainder (for instance, 121′) of cutting a test element group, TEG out of said plurality of remainders of cutting test element groups is located at a region (for instance, NCZ) of said at least one edge exempt from laser beam ablation.

The details and embodiments may vary with respect to what has been disclosed herein and merely by way of example without departing from the extent of protection.

The claims are an integral part of the technical disclosure of embodiments as provided herein.

The extent of protection is determined by the annexed claims.

1. A method of cutting a semiconductor substrate at a cutting line having a length, the method comprising:
selectively applying laser beam ablation energy to the semiconductor substrate at said cutting line to produce at least one ablated region at said cutting line and leave at least one unablated region adjacent to said at least one ablated region along the length of said cutting line; and
blade sawing said semiconductor substrate along the length of said cutting line to produce a cut of said semiconductor substrate both through said at least one ablated region and through said at least one unablated region.

2. The method of claim 1, wherein the semiconductor substrate comprises at least one chipping-prone region at said cutting line and wherein selectively applying comprises applying laser beam ablation energy to said at least one chipping-prone region to produce said at least one ablated region.

3. The method of claim 2, wherein said cut through said at least one ablated region corresponding to the chipping-prone region as a result of said blade sawing exhibits a substantial absence of chipping.

4. The method of claim 1, wherein:
the semiconductor substrate comprises circuitry for at least one test element group at said cutting line; and
selectively applying comprises applying laser beam ablation energy to said at least one test element group at said cutting line to produce said at least one ablated region.

5. The method of claim 4, wherein blade sawing comprises cutting through the at least one ablated region corresponding to said test element group at said cutting line.

6. The method of claim 1, wherein:
the semiconductor substrate comprises circuitry for a plurality of test element groups at said cutting line; and
selectively applying comprises applying laser beam ablation energy to a first test element group of said plurality of test element groups and not applying laser beam ablation energy to a second test element group of said plurality of test element groups.

7. The method of claim 6, wherein blade sawing comprises cutting through both the at least one ablated region corresponding to said first test element group and said second test element group at said cutting line.

8. The method of claim 6, further comprising selecting said second test element group out of said plurality of test element groups as a function of one of: a test element group shape or a test element group length.

9. The method of claim 6, further comprising selecting said second test element group out of said plurality of test element groups as a function of said second test element group having a length less than a critical length along said cutting line.

10. The method of claim 9, wherein said critical length along said cutting line is approximately equal to 250 micron.

11. The method of claim 1, wherein selectively applying laser beam ablation energy to the semiconductor substrate comprises scanning a laser beam in a curvilinear path over at least one region of the semiconductor substrate arranged at said cutting line.

12. The method of claim 11, wherein said curvilinear path is a spiral path.

13. The method of claim 11, wherein said curvilinear path is a closed loop path.

14. A semiconductor product, comprising:
a semiconductor substrate having at least one edge cut at a cutting line having a length;
wherein said at least one edge comprises at least one laser beam ablated region and at least one unablated region along said length; and
wherein said at least one edge is blade cut over the length of said cutting line both through said at least one ablated region and through said at least one unablated region.

15. The semiconductor product of claim 14, comprising at least one remainder of a cut test element group at said at least one edge.

16. The semiconductor product of claim 15, wherein said laser beam ablated region is located at said at least one cut remainder of the test element group.

17. The semiconductor product of claim 15, comprising a plurality of remainders of cut test element groups at said at least one edge, wherein a first remainder of cut test element group of said plurality of remainders of cut test element groups is located at a region of said at least one edge exempt from laser beam ablation and wherein said laser beam ablated region is located at a second remainder of cut test element group of said plurality of remainders of cut test element groups.

18. A method of cutting a semiconductor substrate at a cutting line having a length and including a first test equipment group circuit and second test equipment group circuit, the method comprising:
selectively applying laser beam ablation energy to the first test equipment group at said cutting line to produce an ablated region at said cutting line and leave an unablated region where said second test equipment group circuit is located at said cutting line; and
blade sawing said semiconductor substrate along the length of said cutting line to produce a cut of said semiconductor substrate that extend through both the ablated region and the unablated region, said cut passing through the second test equipment group circuit.

19. The method of claim 18, wherein the semiconductor substrate comprises at least one chipping-prone region at said cutting line due to the presence of the first test equipment group circuit, and wherein selectively applying comprises applying laser beam ablation energy to said at least one chipping-prone region to produce said at least one ablated region.

20. The method of claim 19, wherein said cut through said at least one ablated region corresponding to the chipping-prone region as a result of said blade sawing exhibits a substantial absence of chipping.

21. The method of claim 18, further comprising selecting the second test element group circuit for the unablated region because the second test element group has a certain shape.

22. The method of claim 18, further comprising selecting the second test element group circuit for the unablated region because the second test element group has a certain length.

23. The method of claim 22, wherein said certain length is less than a critical length along said cutting line.

24. The method of claim 23, wherein said critical length along said cutting line is approximately equal to 250 micron.

25. The method of claim 18, wherein selectively applying laser beam ablation energy to the semiconductor substrate comprises scanning a laser beam in a curvilinear path over at least one region of the semiconductor substrate arranged at said cutting line.

26. The method of claim 25, wherein said curvilinear path is a spiral path.

27. The method of claim 25, wherein said curvilinear path is a closed loop path.
